(19) United States
(12) Patent Application Publication
(10) Pub. No.: US 2026/0324108 A1
(43) Pub. Date: Oct. 15, 2026

(54) SOLID-STATE IMAGING ELEMENT AND ELECTRONIC DEVICE

(71) Applicant: SONY SEMICONDUCTOR SOLUTIONS CORPORATION, KANAGAWA (JP)

(72) Inventor: TAKAYA YAMANAKA, KANAGAWA (JP)

(21) Appl. No.: 19/104,260

(22) PCT Filed: Aug. 8, 2023
(86) PCT No.: PCT/JP2023/028855

§ 371 Date: Feb. 17, 2025

(30) Foreign Application Priority Data
Aug. 22, 2022 (JP) 2022-131495

(51) Int. Cl. H10F 39/00; H04N 25/628; H04N 25/771; H04N 25/772; H04N 25/79

(52) U.S. Cl. CPC H10F 39/8037; H04N 25/628; H04N 25/771; H04N 25/772; H04N 25/79; H10F 39/811

(57) ABSTRACT

The present disclosure relates to a solid-state imaging element and an electronic device that are capable of achieving more improved image quality.

The solid-state imaging element includes, for each pixel, a photoelectric conversion unit that photoelectrically converts light into an electric charge; a first FD section that accumulates the electric charge transferred from the photoelectric conversion unit via a transfer transistor to convert the electric charge into a pixel signal; a second FD section that is connected to the first FD section via a connection transistor; and an inter-wire capacitor that is connected to the second FD section to accumulate the electric charge. In addition, the inter-wire capacitor is configured to include a first electrode that is connected to the second FD section and a second electrode that faces the first electrode across a dielectric, and when viewed in a plan view from a logic substrate that is stacked on a sensor substrate on which the photoelectric conversion unit is provided, a wire connected to the second electrode is provided to cover at least the entire second electrode. The present technology can be applied to, for example, a CMOS image sensor with a stacked structure.

### TECHNICAL FIELD

The present disclosure relates to a solid-state imaging element and an electronic device, and particularly to a solid-state imaging element and an electronic device that are capable of achieving more improved image quality.

### BACKGROUND ART

Conventionally, a stacked CMOS (Complementary Metal Oxide Semiconductor) image sensor in which a sensor substrate including photodiodes and a logic substrate including logic circuits are stacked has been used as a solid-state imaging device.

For example, a CMOS image sensor is configured with a plurality of pixels arranged in a required pattern in which each pixel is formed by a photodiode and a plurality of transistors (so-called MOS transistors). A CMOS image sensor has also been developed in which an inter-wire capacitor is connected to a FD (Floating Diffusion) section for accumulating an electric charge transferred from the photodiode for each pixel.

For example, PTL 1 discloses an image sensor in which an inter-wire capacitor having a MIM (Metal-Insulator-Metal) structure provided in a third layer disposed between a first layer including a photodiode and a second layer including a logic circuit accumulates an electric charge.

### CITATION LIST

### Patent Literature

[PTL 1]
U.S. Patent Application Publication No. 2021/0134873 (Specification) (US, A1)

### SUMMARY

### Technical Problem

Incidentally, in the stacked CMOS image sensor as described above, it is known that band noise occurs when the logic substrate is driven, and there is a concern that image quality will be degraded due to the inter-wire capacitor being influenced by the band noise.

In view of such situations, the present disclosure is directed to achieve more improved image quality.

### Solution to Problem

A solid-state imaging element according to one aspect of the present disclosure includes: for each pixel, a photoelectric conversion unit that photoelectrically converts light into an electric charge; a first FD section that accumulates the electric charge transferred from the photoelectric conversion unit via a transfer transistor to convert the electric charge into a pixel signal; a second FD section that is connected to the first FD section via a connection transistor; and an inter-wire capacitor that is connected to the second FD section to accumulate an electric charge, wherein the inter-wire capacitor is configured to include a first electrode that is connected to the second FD section and a second electrode that faces the first electrode across a dielectric, and when viewed in a plan view from a logic substrate that is stacked on a sensor substrate on which the photoelectric conversion unit is provided, a wire connected to the second electrode is provided to cover at least the entire second electrode.

An electronic device of one aspect of the present disclosure includes a solid-state imaging element including: for each pixel, a photoelectric conversion unit that photoelectrically converts light into an electric charge; a first FD section that accumulates the electric charge transferred from the photoelectric conversion unit via a transfer transistor to convert the electric charge into a pixel signal; a second FD section that is connected to the first FD section via a connection transistor; and an inter-wire capacitor that is connected to the second FD section to accumulate an electric charge, wherein the inter-wire capacitor is configured to include a first electrode that is connected to the second FD section and a second electrode that faces the first electrode across a dielectric, and when viewed in a plan view from a logic substrate that is stacked on a sensor substrate on which the photoelectric conversion unit is provided, a wire connected to the second electrode is provided to cover at least the entire second electrode.

In one aspect of the present disclosure, each pixel includes a photoelectric conversion unit that photoelectrically converts light into an electric charge; a first FD section that accumulates the electric charge transferred from the photoelectric conversion unit via a transfer transistor to convert the electric charge into a pixel signal; a second FD section that is connected to the first FD section via a connection transistor; and an inter-wire capacitor that is connected to the second FD section to accumulate an electric charge. In addition, the inter-wire capacitor is configured to include a first electrode that is connected to the second FD section and a second electrode that faces the first electrode across a dielectric, and when viewed in a plan view from a logic substrate that is stacked on a sensor substrate on which the photoelectric conversion unit is provided, a wire connected to the second electrode is provided to cover at least the entire second electrode.

### BRIEF DESCRIPTION OF DRAWINGS

FIG. 1 is a circuit diagram illustrating a first embodiment of a pixel included in an imaging element to which the present technology is applied.

FIG. 2 illustrates an example of drive signals for driving a pixel.

FIG. 3 is a diagram illustrating a configuration example of the pixel in a cross-sectional view.

FIG. 4 is a diagram illustrating a configuration example of three pixels in a plan view.

FIG. 5 is a diagram illustrating a configuration example of a pixel according to a first modification example in a cross-sectional view.

FIG. 6 is a diagram illustrating a configuration example of a pixel according to a second modification example in a cross-sectional view.

FIG. 7 is a circuit diagram illustrating a second embodiment of a pixel included in an imaging element to which the present technology is applied.

FIG. 8 is a diagram illustrating a configuration example of the pixel in a cross-sectional view.

FIG. 9 is a diagram illustrating a configuration example of three pixels in a plan view.

FIG. 10 is a circuit diagram illustrating a third embodiment of a pixel included in an imaging element to which the present technology is applied.

FIG. 11 is a diagram illustrating a configuration example of the pixel in a cross-sectional view.

FIG. 12 is a diagram illustrating a configuration example of an inter-wire capacitor having a three-dimensional structure.

FIG. 13 is a block diagram illustrating a configuration example of an imaging device.

FIG. 14 is a diagram illustrating usage examples of an image sensor.

FIG. 15 is a block diagram illustrating an example of a schematic configuration of a vehicle control system.

FIG. 16 is diagram illustrating an example of installation positions of a vehicle exterior information detection unit and imaging units.

### DESCRIPTION OF EMBODIMENTS

Hereinafter, specific embodiments to which the present technology is applied will be described in detail with reference to the drawings.

### First Configuration Example of Pixel

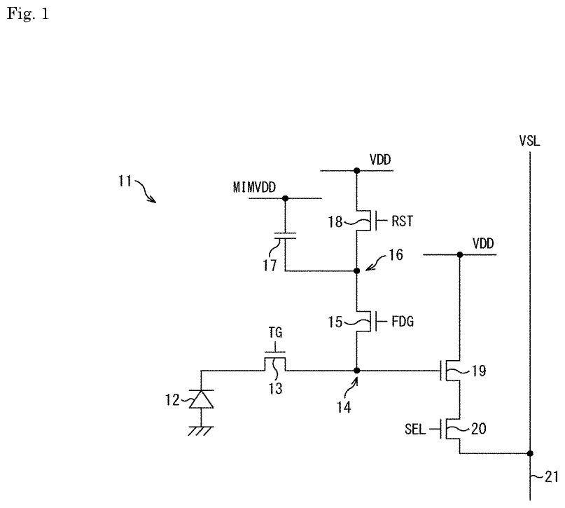

A first embodiment of a pixel included in an imaging element to which the present technology is applied will be described with reference to FIGS. 1 to 6.

FIG. 1 illustrates a circuit diagram of a pixel 11.

As illustrated in FIG. 1, the pixel 11 includes a photoelectric conversion unit 12, a transfer transistor 13, a first FD section 14, a connection transistor 15, a second FD section 16, an inter-wire capacitor 17, a reset transistor 18, an amplifier transistor 19, and a selection transistor 20, and outputs a pixel signal via a vertical signal line 21. For example, the pixel 11 is a LOFIC (Lateral Over Flow Integration Capacitor) pixel, and has a structure in which, when the photoelectric conversion unit 12 is irradiated with light strong enough to exceed the saturation capacity of the photoelectric conversion unit 12, the electric charge overflowing from the photoelectric conversion unit 12 is guided laterally and accumulated in the inter-wire capacitor 17.

The photoelectric conversion unit 12 has an anode terminal grounded, and a cathode terminal connected to the first FD section 14 via the transfer transistor 13. The photoelectric conversion unit 12 receives light with which the light receiving surface of the imaging element is irradiated, and photoelectrically converts the received light into electric charge corresponding to the amount of the light.

The transfer transistor 13 is disposed so as to connect the photoelectric conversion unit 12 and the first FD section 14. The transfer transistor 13 is also driven in accordance with a transfer signal TG, and transfers the electric charge photoelectrically converted by the photoelectric conversion unit 12 to the first FD section 14.

The first FD section 14 accumulates the electric charge transferred from the photoelectric conversion unit 12 via the transfer transistor 13 to convert the electric charge into a pixel signal.

The connection transistor 15 is disposed so as to connect the first FD section 14 and the second FD section 16. The connection transistor 15 is also driven in accordance with a connection signal FDG to turn on/off the connection between the first FD section 14 and the second FD section 16.

The second FD section 16 is connected to the first FD section 14 when the connection transistor 15 is turned on, and accumulates electric charge together with the first FD section 14.

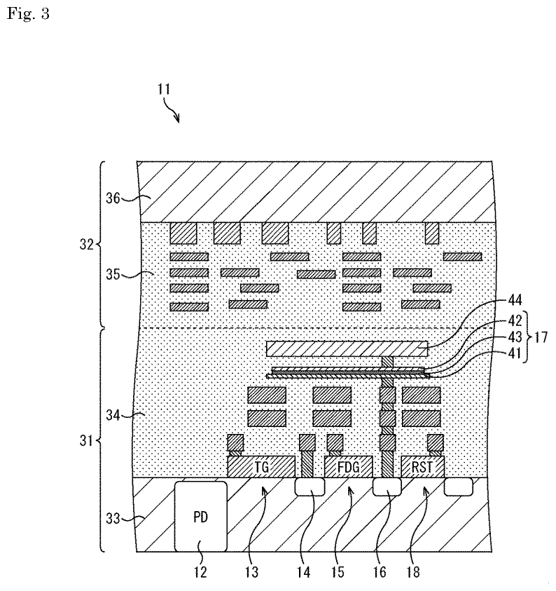

The inter-wire capacitor 17 is configured by a capacitor having a MIM structure provided between wires as described later with reference to FIG. 3, and is disposed so as to connect the second FD section 16 and a signal wire MIMVDD. The inter-wire capacitor 17 accumulates an electric charge in the same manner as the second FD section 16.

The reset transistor 18 is disposed so as to connect the second FD section 16 to a power supply wire VDD. The reset transistor 18 is also driven in accordance with a reset signal RST, and when the connection transistor 15 and the reset transistor 18 are turned on, the electric charges accumulated in the first FD section 14, the second FD section 16, and the inter-wire capacitor 17 are discharged to the power supply wire VDD, thereby resetting the electric charges.

The amplifier transistor 19 has a gate electrode connected to the first FD section 14, and is disposed so as to connect the power supply wire VDD and the selection transistor 20. Then, the amplifier transistor 19 converts the electric charge accumulated by the first FD section 14, or the electric charges accumulated by the first FD section 14, the second FD section 16, and the inter-wire capacitor 17, into a pixel signal of a level corresponding to the electric charge for their respective capacitance.

The selection transistor 20 is disposed so as to connect the amplifier transistor 19 and the vertical signal line 21. The selection transistor 20 is also driven in accordance with a selection signal SEL, and while the selection transistor 20 is on, the pixel signal obtained by conversion of the amplifier transistor 19 is output to the vertical signal line 21.

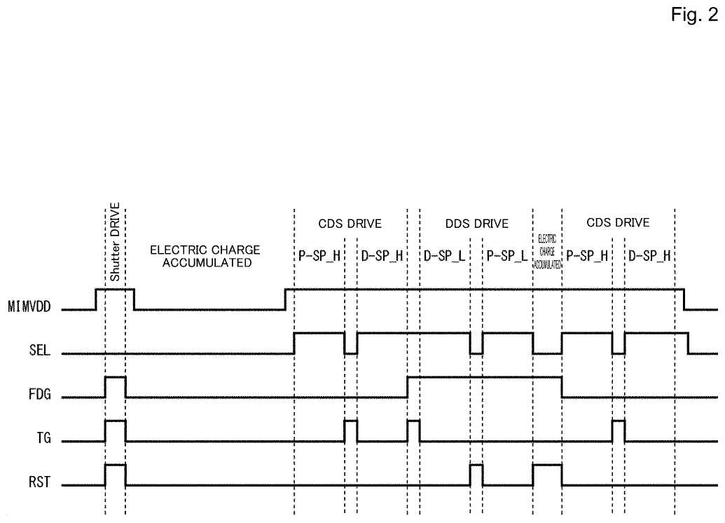

FIG. 2 illustrates an example of drive signals for driving the pixel 11.

As illustrated in FIG. 2, the pixel 11 operates in the order of shutter drive, a first charge accumulation period, a first CDS (Correlated Double Sampling) drive, a DDS (Double Data Sampling) drive, a second charge accumulation period, and a second CDS drive.

In the shutter drive, the connection transistor 15, the transfer transistor 13, and the reset transistor 18 are turned on in a pulsed manner in accordance with the connection signal FDG, the transfer signal TG, and the reset signal RST, respectively, and the electric charges in the pixel 11 are reset accordingly.

In the first charge accumulation period, the pixel 11 is exposed to light for a long period of time, and the electric charge photoelectrically converted in the photoelectric conversion unit 12 by the exposure for the period longer than the second charge accumulation period is accumulated in the photoelectric conversion unit 12.

In the first CDS drive, the connection transistor 15 remains off in accordance with the connection signal FDG, that is, the second FD section 16 and the inter-wire capacitor 17 are not connected to the first FD section 14, and a pixel signal P-SP_H and a pixel signal D-SP_H based on the electric charge accumulated in the photoelectric conversion unit 12 over the first charge accumulation period is read out in sequence. The pixel signal P-SP_H is a pixel signal that is read out when the first FD section 14 is at a reset level. The pixel signal D-SP_H is a pixel signal that is read out when the electric charge transferred from the photoelectric conversion unit 12 in response to turning on the transfer transistor 13 in a pulsed manner in accordance with the transfer signal TG is accumulated in the first FD section 14.

In the DDS drive, the second FD section 16 and the inter-wire capacitor 17 are connected to the first FD section 14 in response to turning on the connection transistor 15 in accordance with the connection signal FDG, and a pixel signal D-SP_L and a pixel signal P-SP_L based on the electric charge accumulated in the photoelectric conversion unit 12 over the first charge accumulation period is read out in sequence. The pixel signal D-SP_L is a pixel signal that is read out when the electric charge transferred from the photoelectric conversion unit 12 in response to turning on the transfer transistor 13 in a pulsed manner in accordance with the transfer signal TG and the electric charge overflowing from the photoelectric conversion unit 12 and accumulated in the inter-wire capacitor 17 are accumulated in the first FD section 14 and the second FD section 16. The pixel signal P-SP_L is a pixel signal that is read out when the accumulated charge is discharged in response to turning on the reset transistor in a pulsed manner in accordance with the reset signal RST, and the first FD section 14, the second FD section 16, and the inter-wire capacitor 17 are at the reset level accordingly.

In the second charge accumulation period, the pixel 11 is exposed to light for a short period of time, and the electric charge photoelectrically converted in the photoelectric conversion unit 12 by the exposure for the period shorter than the first charge accumulation period is accumulated in the photoelectric conversion unit 12.

In the second CDS drive, similarly to the first CDS drive, a pixel signal P-SP_H and a pixel signal D-SP_H based on the electric charge accumulated in the photoelectric conversion unit 12 over the second charge accumulation period is read out in sequence.

Then, in the pixel 11, before the shutter drive is performed, the potential of the signal wire MIMVDD is switched from Lo level (e.g., an intermediate voltage lower than the power supply wire VDD) to Hi level (e.g., the same voltage as the power supply wire VDD), and after the shutter drive is performed, the potential of the signal wire MIMVDD is switched from Hi level to Lo level. After that, in the pixel 11, before the first CDS drive is performed, the potential of the signal wire MIMVDD is switched from Lo level to Hi level, and after the second CDS drive is performed, the potential of the signal wire MIMVDD is switched from Hi level to Lo level. In other words, in the pixel 11, the potential of the signal wire MIMVDD during the first charge accumulation period is controlled to be at Lo level.

By controlling the potential of the signal wire MIMVDD in this manner, in the pixel 11, an increase in noise in the electric charge being accumulated in the photoelectric conversion unit 12 can be suppressed during the first charge accumulation period in which charge is accumulated in the photoelectric conversion unit 12 for a long period of time.

FIG. 3 is a cross-sectional view illustrating a configuration example of the pixel 11.

As illustrated in FIG. 3, a solid-state imaging element has a stacked structure in which a sensor substrate 31 on which the photoelectric conversion unit 12 is provided and a logic substrate 32 on which a logic circuit is provided are stacked. In FIG. 3, a bonding surface between the sensor substrate 31 and the logic substrate 32 is indicated by a dashed line.

The sensor substrate 31 is configured by a semiconductor layer 33 and a wire layer 34 laminated on the front surface of the semiconductor layer 33, and the back surface of the semiconductor layer 33 (the surface facing downward in FIG. 3) is irradiated with light. The logic substrate 32 is configured by a semiconductor layer 36 and a wire layer 35 laminated on the front surface of the semiconductor layer 36. Then, the wire layer 34 of the sensor substrate 31 and the wire layer 35 of the logic substrate 32 are bonded together.

The semiconductor layer 33 includes the photoelectric conversion unit 12, the first FD section 14, and the second FD section 16. In addition, on the front surface of the semiconductor layer 33, the transfer transistor 13 is provided between the photoelectric conversion unit 12 and the first FD section 14, the connection transistor 15 is provided between the first FD section 14 and the second FD section 16, and the reset transistor 18 is provided adjacent to the second FD section 16.

The wire layer 34 is provided with wires in a plurality of layers and electrodes connecting the wires of the layers, and the wire layer 35 is also provided with wires in a plurality of layers. The pixel 11 has a configuration in which the inter-wire capacitor 17 is disposed between the wires provided in the wire layer 34 and the wire layer 35.

In the configuration example illustrated in FIG. 3, the inter-wire capacitor 17 configured by a lower electrode 41 and an upper electrode 42 and a dielectric film 43 sandwiched therebetween is provided in the wire layer 34, and an upper wire 44 connected to the upper electrode 42 is provided in the wire layer 34. For example, Ta/TiN is used for the lower electrode 41 connected to the second FD section 16, TiN is used for the upper electrode 42 that faces the lower electrode 41 across the dielectric film 43, and a high-k film (e.g., a ZrO/AlO/ZrO laminated film) is used for the dielectric film 43.

The lower electrode 41 of the inter-wire capacitor 17 is connected to the second FD section 16 via wires and electrodes in the wire layer 34, and charge overflowing during accumulation is accumulated in the inter-wire capacitor 17 as well as the second FD section 16. The upper electrode 42 of the inter-wire capacitor 17 is connected to the upper wire 44 via an electrode (via) formed so as to penetrate the wire layer 34. The upper wire 44 is shared by pixels 11 arranged in the same row, and is connected to the signal wire MIMVDD outside of the pixel array.

Moreover, the upper wire 44 is provided so as to cover the inter-wire capacitor 17 when viewed in a plan view from the logic substrate 32, and is provided so as to cover at least the entire upper electrode 42, for example. In other words, the pixel 11 is configured so that the upper electrode 42 is completely hidden by the upper wire 44 so as not to be seen when viewed in a plan view from the logic substrate 32. The pixel 11 may be configured such that the lower electrode 41 is hidden by the upper wire 44 so as not to be seen when viewed in a plan view from the logic substrate 32, but for example, the pixel 11 may be configured such that a portion of the lower electrode 41 is exposed from the upper wire 44.

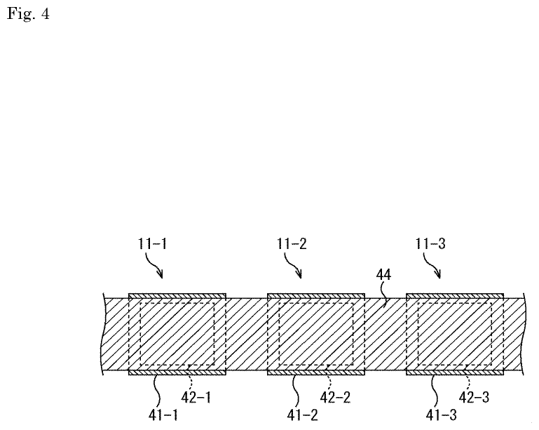

A configuration of the upper wire 44 will be described with reference to FIG. 4. FIG. 4 is a diagram illustrating a schematic configuration example of three pixels 11-1 to 11-3 arranged in the same row when viewed in a plan view from the logic substrate 32.

As illustrated in FIG. 4, the upper wire 44 is provided along the pixels 11-1 to 11-3 arranged in the same row. In each of the pixels 11-1 to 11-3, lower electrodes 41-1 to 41-3 are formed to have a larger area than upper electrodes 42-1 to 42-3, and the outer peripheries of the lower electrodes 41-1 to 41-3 are exposed outside from the upper electrodes 42-1 to 42-3, respectively, when viewed in a plan view from the logic substrate 32.

Also, the pixels 11-1 to 11-3 have a configuration such that, when viewed in a plan view from the logic substrate 32, the upper electrodes 42-1 to 42-3 are fully covered by the upper wire 44 so as not to be seen, while the upper and lower portions of the lower electrodes 41-1 to 41-3 are partially exposed from the upper wire 44. Specifically, the upper wire 44 is laid out so that its width is wider than that of each of the upper electrodes 42-1 to 42-3 and narrower than that of each of the lower electrodes 41-1 to 41-3. Alternatively, both the lower electrodes 41-1 to 41-3 and the upper electrodes 42-1 to 42-3 may be configured to be fully covered by the upper wire 44.

As described above, the pixel 11 is configured so that the upper electrode 42 is fully covered by the upper wire 44, and such that most of the lower electrode 41 is covered by the upper wire 44 (the portion of the lower electrode 41 exposed from the upper wire 44 is minimized), thereby making it possible to suppress the influence of band noise from the logic substrate 32. In other words, the pixel 11 has a structure such that the lower electrode 41 connected to the second FD section 16 is covered by the upper wire 44 connected to the upper electrode 42 in order to shield an FD node of the inter-wire capacitor 17 against band noise. In addition, the upper wire 44 is connected to the signal wire MIMVDD, and therefore it is possible to prevent the FD node of the inter-wire capacitor 17 from being influenced by band noise (e.g., the potential being fluctuated by capacitive coupling with the logic substrate 32).

The pixel 11 is configured as described above, and by suppressing the influence of band noise from the logic substrate 32, improved image quality of the imaging element can be achieved, and image quality at low illuminance levels in particular can be expected to be improved. For example, the influence of band noise can also be suppressed by adding a shielding layer between the logic substrate 32 and the inter-wire capacitor 17 to shield the inter-wire capacitor 17, but the pixel 11 can be made less expensive than with such a configuration.

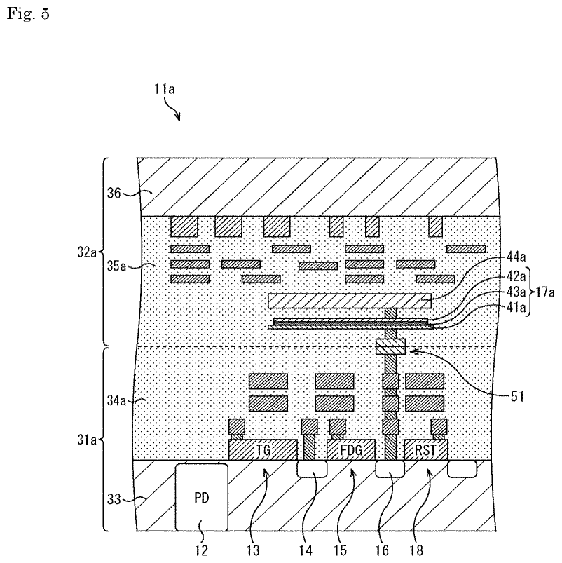

FIG. 5 is a cross-sectional view illustrating a first modification example of a pixel included in an imaging element. In the pixel 11a illustrated in FIG. 5, the same components as those of the pixel 11 of FIG. 3 are denoted by the same reference numerals, and detailed description thereof will be omitted.

As illustrated in FIG. 5, the imaging element is configured by a wire layer 34a of a sensor substrate 31a and a wire layer 35a of a logic substrate 32a, which are bonded together.

The pixel 11 of FIG. 3 has a configuration such that the inter-wire capacitor 17 and the upper wire 44 are provided in the wire layer 34, whereas the pixel 11a is configured so that an inter-wire capacitor 17a and an upper wire 44a are provided in the wire layer 35a. In the pixel 11a, a Cu—Cu bonding portion 51 is provided on the bonding surface between the sensor substrate 31a and the logic substrate 32a, and a lower electrode 41a of the inter-wire capacitor 17a is connected to the second FD section 16 via the Cu—Cu bonding portion 51.

As described above, the pixel 11a has a configuration in which the inter-wire capacitor 17a and the upper wire 44a, which are disposed between wires provided in the wire layer 34a and the wire layer 35a, are disposed on the wire layer 35a side of the logic substrate 32a. Also, as with the pixel 11 of FIG. 3, in the pixel 11a, the upper wire 44a is provided so as to cover the inter-wire capacitor 17a when viewed in a plan view from the logic substrate 32a, for example, the upper wire 44a is provided so as to cover at least the entire upper electrode 42a.

Therefore, as with the pixel 11 of FIG. 3, the pixel 11a can suppress the influence of band noise from the logic substrate 32a.

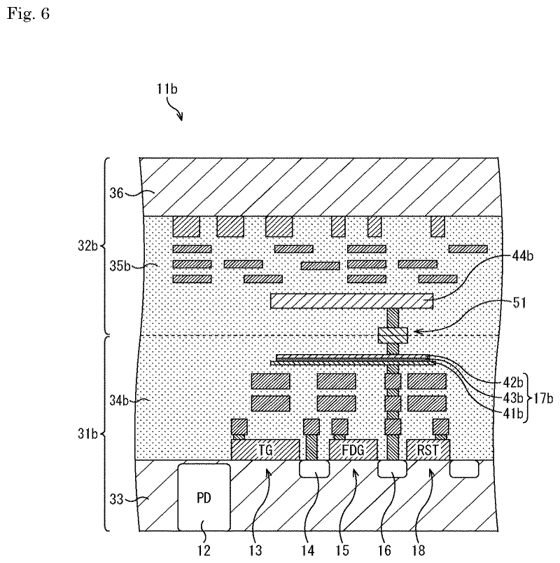

FIG. 6 is a cross-sectional view illustrating a second modification example of a pixel included in an imaging element. In the pixel 11b illustrated in FIG. 6, the same components as those of the pixel 11 of FIG. 3 are denoted by the same reference numerals, and detailed description thereof will be omitted.

As illustrated in FIG. 6, the imaging element is configured by a wire layer 34b of a sensor substrate 31b and a wire layer 35b of a logic substrate 32b, which are bonded together.

The pixel 11 of FIG. 3 has a configuration such that the inter-wire capacitor 17 and the upper wire 44 are provided in the wire layer 34, whereas the pixel 11b has a configuration such that an inter-wire capacitor 17b is provided in the wire layer 34b and an upper wire 44b is provided in the wire layer 35b. In the pixel 11b, a Cu—Cu bonding portion 51 is provided on the bonding surface between the sensor substrate 31b and the logic substrate 32b, and the inter-wire capacitor 17b is connected to the upper wire 44b via the Cu—Cu bonding portion 51.

As described above, the pixel 11b has a configuration such that the inter-wire capacitor 17b and the upper wire 44b, which are disposed between wires provided in the wire layer 34b and the wire layer 35b, are separately disposed in the wire layer 34b of the sensor substrate 31b and in the wire layer 35b of the logic substrate 32b, respectively. Also, as with the pixel 11 of FIG. 3, in the pixel 11b, the upper wire 44b is provided so as to cover the inter-wire capacitor 17b when viewed in a plan view from the logic substrate 32b, for example, the upper wire 44b is provided so as to cover at least the entire upper electrode 42b.

Therefore, as with the pixel 11 of FIG. 3, the pixel 11b can suppress the influence of band noise from the logic substrate 32b.

### Second Configuration Example of Pixel

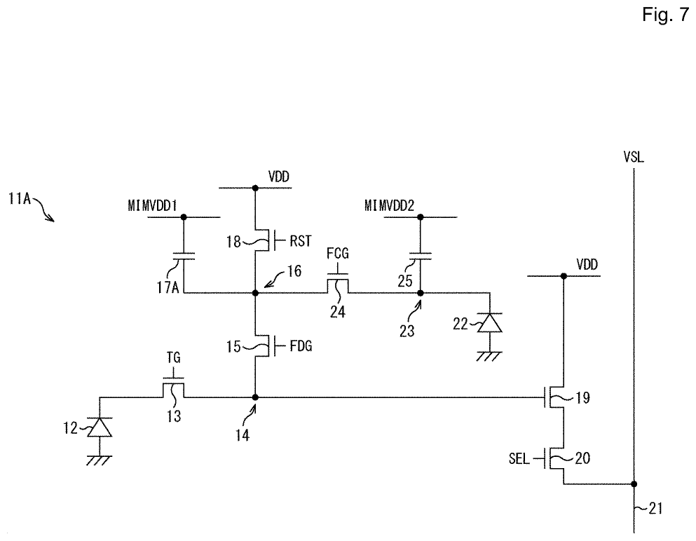

A second embodiment of a pixel included in an imaging element to which the present technology is applied will be described with reference to FIGS. 7 to 9. In the pixel 11A illustrated in FIGS. 7 to 9, the same components as those of the pixel 11 of FIGS. 1 to 4 are denoted by the same reference numerals, and detailed description thereof will be omitted.

FIG. 7 illustrates a circuit diagram of the pixel 11a.

As illustrated in FIG. 7, the pixel 11A is configured to include the photoelectric conversion unit 12, the transfer transistor 13, the first FD section 14, the connection transistor 15, the second FD section 16, an inter-wire capacitor 17A, the reset transistor 18, the amplifier transistor 19, and the selection transistor 20, as with the pixel 11 of FIG. 1. Furthermore, the pixel 11A is configured to include a second photoelectric conversion unit 22, a third FD section 23, a second connection transistor 24, and a second inter-wire capacitor 25.

The second photoelectric conversion unit 22 has an anode terminal grounded and a cathode terminal connected to the third FD section 23. The second photoelectric conversion unit 22 receives light with which the light receiving surface of the imaging element is irradiated, and photoelectrically converts the received light into electric charge corresponding to the amount of the light. The second photoelectric conversion unit 22 has a sub-pixel structure in which it has a light receiving area smaller than that of the photoelectric conversion unit 12.

The third FD section 23 accumulates the electric charge photoelectrically converted by the second photoelectric conversion unit 22 to convert the electric charge into a pixel signal.

The second connection transistor 24 is disposed so as to connect the second FD section 16 and the third FD section 23. The second connection transistor 24 is driven in accordance with a connection signal FCG to turn on/off the connection between the second FD section 16 and the third FD section 23.

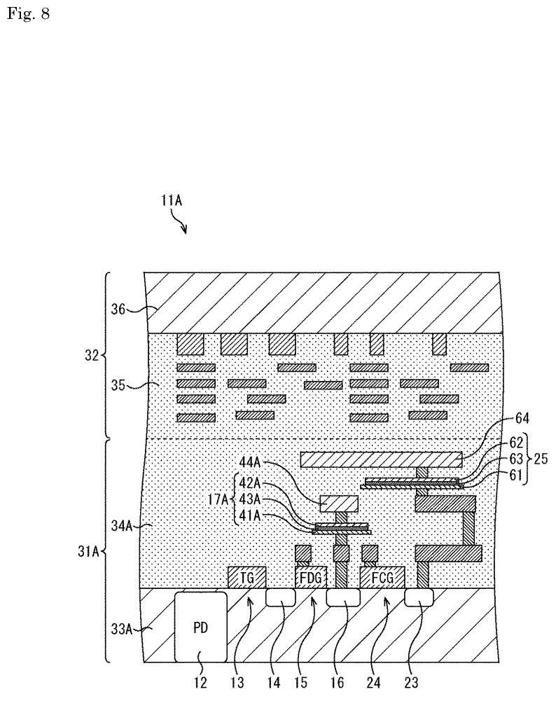

The second inter-wire capacitor 25 is configured by a capacitor having a MIM structure provided between wires as described later with reference to FIG. 8, and is disposed so as to connect the third FD section 23 and a signal wire MIMVDD2. The second inter-wire capacitor 25 accumulates an electric charge together with the third FD section 23.

FIG. 8 is a cross-sectional view illustrating a configuration example of the pixel 11A.

As illustrated in FIG. 8, the imaging element is configured by a wire layer 34A of a sensor substrate 31A and the wire layer 35 of the logic substrate 32, which are bonded together. A semiconductor layer 33A of the sensor substrate 31A includes the photoelectric conversion unit 12, the first FD section 14, the second FD section 16, and the third FD section 23. Also, on the front surface of the semiconductor layer 33, the transfer transistor 13 is provided between the photoelectric conversion unit 12 and the first FD section 14, the connection transistor 15 is provided between the first FD section 14 and the second FD section 16, and the second connection transistor 24 is provided between the second FD section 16 and the third FD section 23.

The pixel 11A is configured so that the inter-wire capacitor 17A and the second inter-wire capacitor 25 are disposed between wires provided in the wire layer 34A and the wire layer 35.

In the configuration example illustrated in FIG. 8, as with the inter-wire capacitor 17 in FIG. 3, the inter-wire capacitor 17A is provided in the wire layer 34A, which is configured by a lower electrode 41A and an upper electrode 42A and a dielectric film 43A sandwiched therebetween, and an upper wire 44A connected to the upper electrode 42A is provided in the wire layer 34A. The lower electrode 41A of the inter-wire capacitor 17A is connected to the second FD section 16 via wires and electrodes in the wire layer 34A, and when the connection transistor 15 is turned on, charge is accumulated in the inter-wire capacitor 17A as well as the second FD section 16.

The second inter-wire capacitor 25 is configured by a lower electrode 61 and an upper electrode 62 and a dielectric film 63 sandwiched therebetween, and an upper wire 64 connected to the upper electrode 62 is provided in the wire layer 34A. The lower electrode 61 of the second inter-wire capacitor 25 is connected to the third FD section 23 via wires and electrodes in the wire layer 34A, and the electric charge photoelectrically converted in the second photoelectric conversion unit 22 is accumulated in the second inter-wire capacitor 25 as well as the third FD section 23.

The pixel 11A may be configured such that the inter-wire capacitor 17A and the second inter-wire capacitor 25 are disposed between the same pair of wires, or may be configured such that each of them is disposed between a different pair of wires. In the illustrated example, the second inter-wire capacitor 25 is disposed closer to the logic substrate 32 than the inter-wire capacitor 17A, and this arrangement makes a configuration in which the inter-wire capacitor 17A and the second inter-wire capacitor 25 are covered by the upper wire 64.

In other words, the pixel 11A is configured so that the upper wire 64 is provided so as to cover the inter-wire capacitor 17A and the second inter-wire capacitor 25 when viewed in a plan view from the logic substrate 32, for example, the upper wire 64 is provided to so as cover at least the entire upper electrode 42A and the entire upper electrode 62.

In the pixel 11A, even if the upper electrode 42A of inter-wire capacitor 17A is not fully covered by the upper wire 44A, it is sufficient that a configuration is made in which the upper electrode 42A of the inter-wire capacitor 17A is fully covered by the upper wire 64. This prevents an FD node of the inter-wire capacitor 17A from being influenced by band noise, making it possible to improve the degree of freedom in wiring, for example.

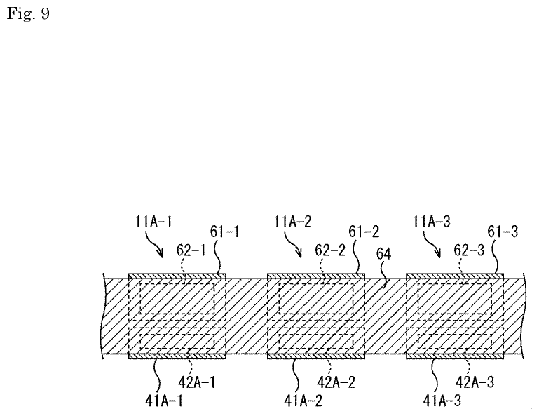

A configuration of the upper wire 64 will be described with reference to FIG. 9. FIG. 9 is a diagram illustrating a schematic configuration example of three pixels 11A-1 to 11A-3 arranged in the same row when viewed in a plan view from the logic substrate 32.

As illustrated in FIG. 9, the upper wire 64 is provided along the pixels 11A-1 to 11A-3 arranged in the same row. In the pixels 11A-1 to 11A-3, lower electrodes 41A-1 to 41A-3 are formed to have a larger area than upper electrodes 42A-1 to 42A-3, and lower electrodes 61-1 to 61-3 are formed to have a larger area than upper electrodes 62-1 to 62-3, respectively. Therefore, when viewed in a plan view from the logic substrate 32, the outer peripheries of the lower electrodes 41-1 to 41-3 are exposed outside from the upper electrodes 42-1 to 42-3, respectively, and the outer peripheries of the lower electrodes 61-1 to 61-3 are exposed outside from the upper electrodes 62-1 to 62-3, respectively.

The pixels 11A-1 to 11A-3 have a configuration such that the upper electrodes 42A-1 to 42A-3 and the upper electrodes 62-1 to 62-3 are fully covered by the upper wire 64 so as not to be seen when viewed in a plan view from the logic substrate 32. On the other hand, the pixels 11A-1 to 11A-3 have a configuration such that lower portions of the lower electrodes 41A-1 to 41A-3 and upper portions of the lower electrodes 61-1 to 61-3 are partially exposed from the upper wire 64. Alternatively, both of the lower electrodes 41A-1 to 41A-3 and the upper electrodes 42A-1 to 42A-3, and both of the lower electrodes 61-1 to 61-3 and the upper electrodes 62-1 to 62-3 may be configured to be fully covered by the upper wire 64.

The pixel 11A is configured as described above, and as with the pixel 11 of FIGS. 1 to 4, by suppressing the influence of band noise from the logic substrate 32, improved image quality of the imaging element can be achieved.

### Third Configuration Example of Pixel

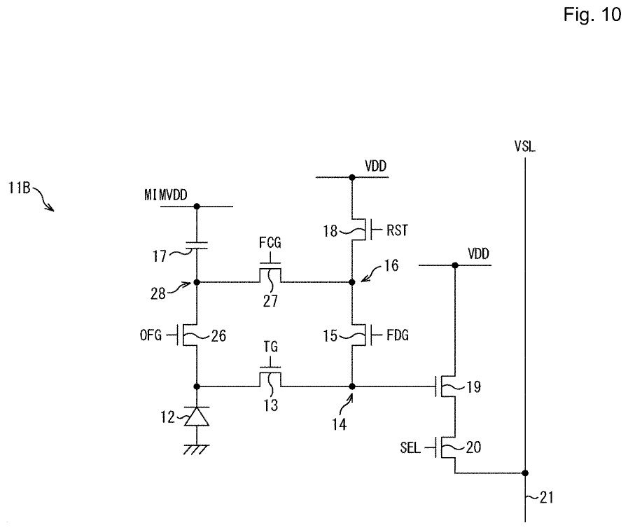

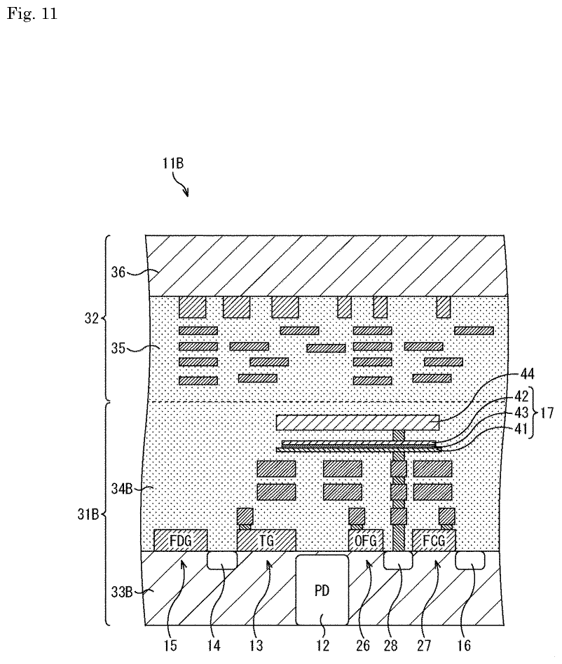

A third embodiment of a pixel included in an imaging element to which the present technology is applied will be described with reference to FIGS. 10 and 11. In the pixel 11B illustrated in FIGS. 10 and 11, the same components as those of the pixel 11 of FIGS. 1 to 4 are denoted by the same reference numerals, and detailed description thereof will be omitted.

FIG. 10 illustrates a circuit diagram of the pixel 11b.

As illustrated in FIG. 10, the pixel 11B is configured to include the photoelectric conversion unit 12, the transfer transistor 13, the first FD section 14, the connection transistor 15, the second FD section 16, the inter-wire capacitor 17, the reset transistor 18, the amplifier transistor 19, and the selection transistor 20, as with the pixel 11 of FIG. 1. In addition, the pixel 11B is configured to include an overflow transistor 26, a third connection transistor 27, and a fourth FD section 28. For example, the pixel 11B is an OFG (Over Flow Gate) type of LOFIC pixel.

The overflow transistor 26 is disposed so as to connect the photoelectric conversion unit 12 and the fourth FD section 28, and when the photoelectric conversion unit 12 is irradiated with light strong enough to exceed its saturation capacity, the overflow transistor 26 causes the electric charge overflowing from the photoelectric conversion unit 12 to overflow into the fourth FD section 28. The overflow transistor 26 is also driven in accordance with a transfer signal OFG, and transfers the electric charge photoelectrically converted by the photoelectric conversion unit 12 to the fourth FD section 28.

The third connection transistor 27 is disposed so as to connect the second FD section 16 and the fourth FD section 28. The third connection transistor 27 is also driven in accordance with a connection signal FCG to turn on/off the connection between the second FD section 16 and the fourth FD section 28.

The fourth FD section 28 accumulates the electric charge overflowing from the photoelectric conversion unit 12 via the overflow transistor 26 to convert the electric charge into a pixel signal. Furthermore, the inter-wire capacitor 17 is connected to the fourth FD section 28, and electric charge is accumulated in the inter-wire capacitor 17 as well as the fourth FD section 28. The fourth FD section 28 is also connected to the second FD section 16 when the third connection transistor 27 is turned on, and reads out the electric charge together with the second FD section 16.

As described above, the pixel 11B has a configuration such that, when the photoelectric conversion unit 12 is irradiated with light strong enough to exceed the saturation capacity of the photoelectric conversion unit 12, electric charge overflowing from the photoelectric conversion unit 12 overflows via the overflow transistor 26 and is accumulated in the fourth FD section 28 and the inter-wire capacitor 17.

FIG. 11 is a cross-sectional view illustrating a configuration example of the pixel 11B.

As illustrated in FIG. 11, the imaging element is configured by a wire layer 34B of a sensor substrate 31B and the wire layer 35 of the logic substrate 32, which are bonded together. A semiconductor layer 33B of the sensor substrate 31B includes the photoelectric conversion unit 12, the first FD section 14, the second FD section 16, and the fourth FD section 28. Also, on the front surface of the semiconductor layer 33, the transfer transistor 13 is provided between the photoelectric conversion unit 12 and the first FD section 14, the connection transistor 15 is provided adjacent to the first FD section 14, the overflow transistor 26 is provided between the photoelectric conversion unit 12 and the fourth FD section 28, and the third connection transistor 27 is provided between the fourth FD section 28 and the second FD section 16.

The pixel 11B is configured so that the inter-wire capacitor 17 is disposed between wires provided in the wire layer 34B and the wire layer 35, and the lower electrode 41 of the inter-wire capacitor 17 is connected to the fourth FD section 28. Also, the inter-wire capacitor 17 and the upper wire 44 of the pixel 11B are configured as with the pixel 11 of FIG. 3, and the upper wire 44 is provided so as to cover the inter-wire capacitor 17 when viewed in a plan view from the logic substrate 32, for example, the upper wire 44 is provided so as to cover at least the entire upper electrode 42.

The pixel 11B is configured as described above, and as with the pixel 11 of FIGS. 1 to 4, by suppressing the influence of band noise from the logic substrate 32, improved image quality of the imaging element can be achieved.

### Configuration Example of Inter-Wire Capacitor With Three-Dimensional Structure

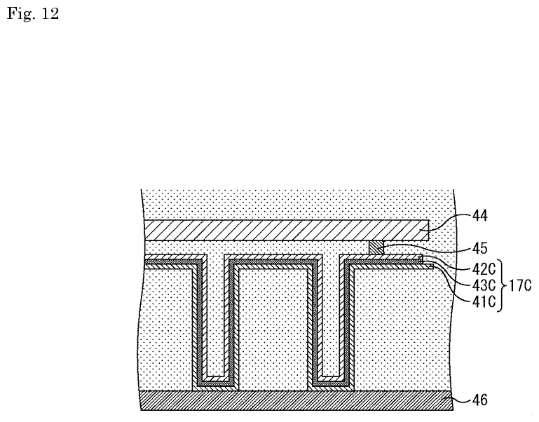

An inter-wire capacitor 17C with a three-dimensional structure will be described with reference to FIG. 12.

As described above, for example, the inter-wire capacitor 17 provided in the pixel 11 has a two-dimensional structure in which the dielectric film 43 is sandwiched between the lower electrode 41 and the upper electrode 42, which are formed planarly. Instead of the inter-wire capacitor 17 having such a planar structure, the pixel 11 of the above-described embodiments including modification examples may employ the inter-wire capacitor 17C with a three-dimensional structure.

As illustrated in FIG. 12, for the inter-wire capacitor 17C with a three-dimensional structure, for example, a plurality of cylindrical openings are formed in an interlayer film so as to open up to the lower wire 46, and a lower electrode 41C is formed into a three-dimensional shape that runs over the inside of the plurality of openings and connects to the lower wire 46. Subsequently, a dielectric film 43C is formed so as to be laminated on the lower electrode 41C, and an upper electrode 42C is formed into a three-dimensional shape so as to sandwich the dielectric film 43C between the upper electrode 42C and the lower electrode 41C, and then the upper electrode 42C is connected to the upper wire 44 via a through electrode 45. As described above, the inter-wire capacitor 17C with a three-dimensional structure is three-dimensionally configured in the plurality of openings formed in the interlayer film, with the dielectric film 43C sandwiched between the lower electrode 41C and upper electrode 42C along the cylindrically shape of the openings.

For example, by employing the inter-wire capacitor 17C with a three-dimensional structure, the area of the dielectric film 43C to be sandwiched can be increased, and the capacity of electric charge to be accumulated can be increased. In the imaging element including such a pixel 11, a wider dynamic range can be expected.

### Configuration Example of Electronic Device

The imaging element including the pixels 11 described above can be applied to various electronic devices including an imaging system such as a digital still camera and a digital video camera, a cellular phone having an imaging function, or any other device having an imaging function.

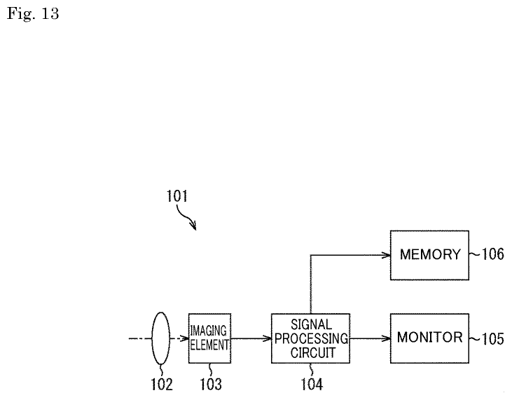

FIG. 13 is a block diagram of an exemplary configuration of an imaging device mounted in an electronic device.

As illustrated in FIG. 9, the imaging device 101 includes an optical system 102, an imaging element 103, a signal processing circuit 104, a monitor 105, and a memory 106, and is capable of capturing still and moving images.

The optical system 102 is configured to include one or more lenses, guides light (incident light) from a subject to the imaging element 103, and forms an image on the light-receiving surface of the imaging element 103.

As the imaging element 103, an imaging element including the above-described pixels 11 is used. In the imaging element 103, electrons are accumulated for a certain period of time according to the image formed on the light-receiving surface via the optical system 102. A signal corresponding to the electrons accumulated in the imaging element 103 is then supplied to the signal processing circuit 104.

The signal processing circuit 104 carries out various types of signal processing to pixel signals output from the imaging element 103. The image (image data) obtained by the signal processing carried out by the signal processing circuit 104 is supplied to the monitor 105 for display or to the memory 106 for storage (recording).

By applying the imaging element including the above-described pixels 11 to the imaging device 101 thus configured, for example, more improved image quality can be achieved.

### Usage Example of Image Sensor

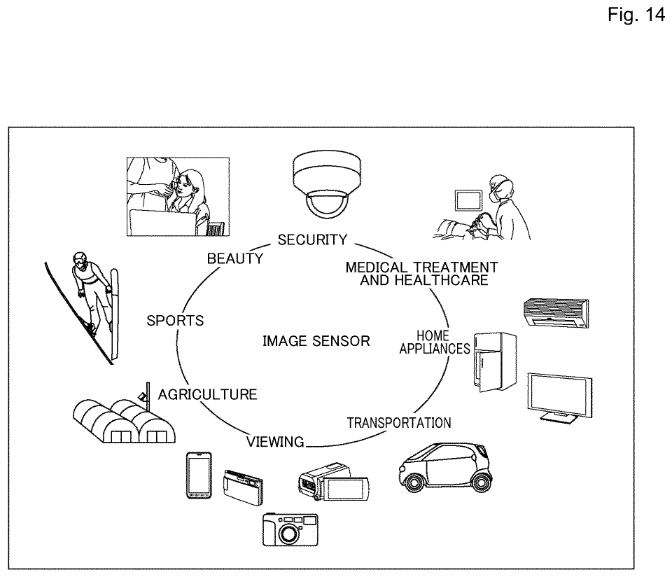

FIG. 14 is a diagram illustrating usage examples of how the above-described image sensor (imaging element) is used.

The above-described image sensor can be used, for example, in various cases for sensing light such as visible light, infrared light, ultraviolet light, and X-ray, as will be described.
Devices that capture images used for viewing, such as digital cameras and mobile devices with camera functions
Devices used for transportation, such as in-vehicle sensors that capture front, rear, surrounding, and interior view images of automobiles, monitoring cameras that monitor traveling vehicles and roads, ranging sensors that measure a distance between vehicles, and the like, for safe driving such as automatic stop, recognition of a driver's condition, and the like
Devices used for home appliances such as TVs, refrigerators, and air conditioners in order to capture an image of a user's gesture and perform device operations in accordance with the gesture
Devices used for medical treatment and healthcare, such as endoscopes and devices that perform angiography by receiving infrared light
Devices used for security, such as monitoring cameras for crime prevention and cameras for personal authentication
Devices used for beauty, such as a skin measuring device that captures images of the skin and a microscope that captures images of the scalp
Devices used for sports, such as action cameras and wearable cameras for sports applications
Devices used for agriculture, such as cameras for monitoring conditions of fields and crops

The technology according to the present disclosure (the present technology) can be applied to various products. For example, the technology according to the present disclosure may be realized as a device mounted in any type of moving body such as an automobile, an electric vehicle, a hybrid electric vehicle, a motorcycle, a bicycle, a personal mobility device, an airplane, a drone, a ship, and a robot.

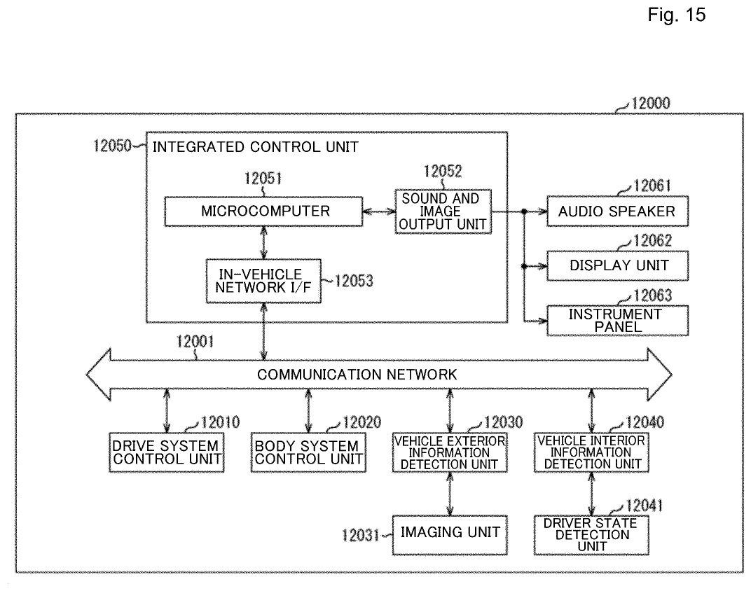

FIG. 15 is a block diagram illustrating a schematic configuration example of a vehicle control system, which is an example of a moving body control system to which the technology according to the present disclosure can be applied.

The vehicle control system 12000 includes a plurality of electronic control units connected to one another via a communication network 12001. In the example illustrated in FIG. 15, the vehicle control system 12000 includes a drive system control unit 12010, a body system control unit 12020, a vehicle exterior information detection unit 12030, a vehicle interior information detection unit 12040, and an integrated control unit 12050. A microcomputer 12051, a sound and image output unit 12052, and an in-vehicle network I/F (Interface) 12053 are illustrated as the functional configuration of the integrated control unit 12050.

The drive system control unit 12010 controls operations of devices related to a drive system of a vehicle according to various programs. For example, the drive system control unit 12010 functions as a control device for a driving force generation device for generating a driving force of a vehicle such as an internal combustion engine or a driving motor, a driving force transmission mechanism for transmitting a driving force to wheels, a steering mechanism for adjusting a turning angle of a vehicle, and a braking device that generates a braking force of a vehicle.

The body system control unit 12020 controls operations of various devices mounted in the vehicle body according to various programs. For example, the body system control unit 12020 functions as a control device for a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, a lamp of the vehicle, and the like.

The vehicle exterior information detection unit 12030 detects information on the outside of the vehicle equipped with the vehicle control system 12000. For example, an imaging unit 12031 is connected to the vehicle exterior information detection unit 12030. The vehicle exterior information detection unit 12030 causes the imaging unit 12031 to capture an image outside of the vehicle and receives the captured image. The vehicle exterior information detection unit 12030 may perform object detection processing or distance detection processing for people, cars, obstacles, signs, and letters on the road on the basis of the received image.

The imaging unit 12031 is an optical sensor that receives light and outputs an electrical signal according to the amount of the received light. The imaging unit 12031 can also output the electrical signal as an image or distance measurement information. In addition, the light received by the imaging unit 12031 may be visible light or invisible light such as infrared light.

The vehicle interior information detection unit 12040 detects information on the inside of the vehicle. For example, a driver state detection unit 12041 that detects a driver's state is connected to the vehicle interior information detection unit 12040. The driver state detection unit 12041 includes, for example, a camera that captures an image of a driver, and the vehicle interior information detection unit 12040 may calculate a degree of fatigue or concentration of the driver or may determine whether or not the driver is dozing on the basis of detection information input from the driver state detection unit 12041.

The microcomputer 12051 can calculate control target values for the driving force generation device, the steering mechanism, or the braking device on the basis of information on the inside and outside of the vehicle, the information being acquired by the vehicle exterior information detection unit 12030 or the vehicle interior information detection unit 12040, and the microcomputer 12051 can output control commands to the drive system control unit 12010. For example, the microcomputer 12051 can perform cooperative control for the purpose of implementing the functions of an ADAS (Advanced Driver Assistance System) including vehicle collision avoidance, impact mitigation, following traveling based on an inter-vehicle distance, vehicle speed maintenance driving, vehicle collision warning, and vehicle lane deviation warning.

Further, the microcomputer 12051 can perform cooperative control for the purpose of automated driving or the like in which autonomous travel is performed without depending on operations of the driver, by controlling the driving force generation device, the steering mechanism, or the braking device and the like on the basis of information about the surroundings of the vehicle, the information being acquired by the vehicle exterior information detection unit 12030 or the vehicle interior information detection unit 12040.

In addition, the microcomputer 12051 can output a control command to the body system control unit 12030 based on the information outside of the vehicle acquired by the vehicle exterior information detection unit 12030. For example, the microcomputer 12051 can perform coordinated control for the purpose of antiglare such as switching a high beam to a low beam by controlling a headlamp according to a position of a preceding vehicle or an oncoming vehicle detected by the vehicle exterior information detection unit 12030.

The sound and image output unit 12052 transmits an output signal of at least one of sound and an image to an output device capable of visually or audibly notifying a passenger or the outside of the vehicle of information. In the example illustrated in FIG. 15, an audio speaker 12061, a display unit 12062, and an instrument panel 12063 are illustrated as output devices. The display unit 12062 may include at least one of an on-board display and a head-up display, for example.

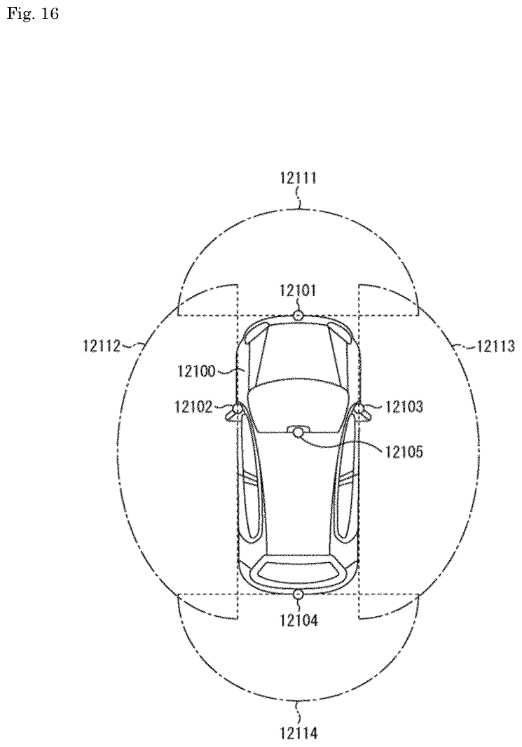

FIG. 16 is a diagram illustrating an example of installation positions of imaging units 12031.

In FIG. 16, the imaging units 12031 include imaging units 12101, 12102, 12103, 12104, and 12105.

The imaging units 12101, 12102, 12103, 12104, and 12105 are provided at, for example, positions of a front nose, side mirrors, a rear bumper, a back door, an upper portion of a vehicle internal front windshield inside of the vehicle, and the like of the vehicle 12100. The imaging unit 12101 provided at the front nose and the imaging unit 12105 provided in an upper portion of the vehicle internal front windshield mainly acquire images in front of the vehicle 12100. The imaging units 12102 and 12103 provided at the side mirrors mainly acquire images on the lateral sides of the vehicle 12100. The imaging unit 12104 provided at the rear bumper or the back door mainly acquires rear view images of the vehicle 12100. The imaging unit 12105 provided at the upper portion of the vehicle internal front windshield is mainly used for detection of a preceding vehicle, a pedestrian, an obstacle, a traffic signal, a traffic sign, a lane, or the like.

FIG. 16 illustrates an example of imaging ranges of the imaging units 12101 to 12104. An imaging range 12111 indicates an imaging range of the imaging unit 12101 provided at the front nose, imaging ranges 12112 and 12113 respectively indicate the imaging ranges of the imaging units 12102 and 12103 provided at the side mirrors, and an imaging range 12114 indicates the imaging range of the imaging unit 12104 provided at the rear bumper or the back door. For example, by superimposing image data captured by the imaging units 12101 to 12104, it is possible to obtain a bird's-eye view image viewed from the upper side of the vehicle 12100.

At least one of the imaging units 12101 to 12104 may have a function for obtaining distance information. For example, at least one of the imaging units 12101 to 12104 may be a stereo camera constituted by a plurality of imaging elements or may be an imaging element that has pixels for phase difference detection.

For example, the microcomputer 12051 can extract, in particular, a closest three-dimensional object on a traveling path of the vehicle 12100, which is a three-dimensional object traveling at a predetermined speed (e.g., 0 km/h or higher) in the substantially same direction as the vehicle 12100, as a vehicle ahead by obtaining a distance to each three-dimensional object in the imaging ranges 12111 to 12114 and temporal change in the distance (a relative speed with respect to the vehicle 12100) on the basis of distance information obtained from the imaging units 12101 to 12104. The microcomputer 12051 can also set a distance to be secured from a vehicle ahead and perform automatic brake control (including following stop control) and automatic acceleration control (including following start control). Thus, cooperative control can be performed for the purpose of, for example, automated driving in which autonomous driving is performed without operations of the driver.

For example, the microcomputer 12051 can classify and extract three-dimensional data regarding three-dimensional objects into other three-dimensional objects such as a two-wheeled vehicle, an ordinary vehicle, a large-size vehicle, a pedestrian, and an electric pole on the basis of distance information obtained from the imaging units 12101 to 12104 and can use the other three-dimensional objects to perform automated avoidance of obstacles. For example, the microcomputer 12051 differentiates surrounding obstacles of the vehicle 12100 into obstacles which can be viewed by the driver of the vehicle 12100 and obstacles which are difficult to view. Then, the microcomputer 12051 determines a collision risk indicating the degree of risk of collision with each obstacle, and when the collision risk is equal to or higher than a set value and there is a possibility of collision, an alarm is output to the driver through the audio speaker 12061 or the display unit 12062, forced deceleration or avoidance steering is performed through the drive system control unit 12010, and thus it is possible to perform driving support for collision avoidance.

At least one of the imaging units 12101 to 12104 may be an infrared camera that detects infrared light. For example, the microcomputer 12051 can recognize a pedestrian by determining whether or not a pedestrian is present in captured images of the imaging units 12101 to 12104. Such recognition of the pedestrian is performed using, for example, a procedure for extracting feature points in the captured images of the imaging units 12101 to 12104 serving as infrared cameras, and a procedure for performing pattern matching processing on a series of feature points indicating a contour of an object to determine whether the object is a pedestrian. When the microcomputer 12051 determines that there is a pedestrian in the captured images of the imaging units 12101 to 12104, and the pedestrian is recognized, the sound and image output unit 12052 controls the display unit 12062 so that the recognized pedestrian is superimposed and displayed with a square contour line for emphasis. In addition, the sound and image output unit 12052 may control the display unit 12062 so that an icon indicating a pedestrian or the like is displayed at a desired position.

An example of the vehicle control system to which the technology according to the present disclosure can be applied has been described above. The technology according to the present disclosure can be applied to the imaging unit 12031 and the like in the above-described configuration. By applying the technology according to the present disclosure to the imaging unit 12031, images can be obtained with less noise even in a dark environment.

### Combination Example of Configuration

The present technology can also be configured as follows.
(1)

A solid-state imaging element including: for each pixel,
a photoelectric conversion unit that photoelectrically converts light into an electric charge;
a first FD (Floating Diffusion) section that accumulates the electric charge transferred from the photoelectric conversion unit via a transfer transistor to convert the electric charge into a pixel signal;
a second FD section that is connected to the first FD section via a connection transistor; and
an inter-wire capacitor that is connected to the second FD section to accumulate the electric charge,
wherein
the inter-wire capacitor is configured to include a first electrode that is connected to the second FD section and a second electrode that faces the first electrode across a dielectric, and
when viewed in a plan view from a logic substrate that is stacked on a sensor substrate on which the photoelectric conversion unit is provided, a wire connected to the second electrode is provided to cover at least the entire second electrode.
(2)

The solid-state imaging element according to (1), the solid-state imaging element has a structure in which, when the photoelectric conversion unit is irradiated with light strong enough to exceed a saturation capacity of the photoelectric conversion unit, the electric charge overflowing from the photoelectric conversion unit is accumulated in the inter-wire capacitor.
(3)

The solid-state imaging element according to (1) or (2), wherein a potential of the wire connected to the second electrode of the inter-wire capacitor is controlled to be at Lo level during a charge accumulation period in which the pixel is exposed to light for a long period of time and the electric charge is accumulated in the photoelectric conversion unit.
(4)

The solid-state imaging element according to any one of (1) to (3), wherein the inter-wire capacitor and the wire are disposed in a wire layer on the sensor substrate side.
(5)

The solid-state imaging element according to any one of (1) to (3), wherein the inter-wire capacitor and the wire are disposed in a wire layer on the logic substrate side.
(6)

The solid-state imaging element according to any one of (1) to (3), wherein the inter-wire capacitor is disposed in a wire layer on the sensor substrate side, and the wire is disposed in a wire layer on the logic substrate side.
(7)

The solid-state imaging element according to any one of (1) to (6), wherein the pixel includes
a second photoelectric conversion unit having a smaller light receiving area than the photoelectric conversion unit, and
a third FD section that accumulates an electric charge photoelectrically converted by the second photoelectric conversion unit to convert the electric charge into a pixel signal,
wherein
the inter-wire capacitor is connected to the third FD section via a second connection transistor.
(8)

The solid-state imaging element according to (7), a second inter-wire capacitor including a third electrode that is connected to the third FD section and a fourth electrode that faces the third electrode across a dielectric.
(9)

The solid-state imaging element according to (8), wherein the inter-wire capacitor and the second inter-wire capacitor are covered by one of a wire connected to the second electrode of the inter-wire capacitor and a wire connected to the third electrode of the second inter-wire capacitor when viewed in a plan view from the logic substrate.
(10)

The solid-state imaging element according to any one of (1) to (6), further including an overflow transistor that, when the photoelectric conversion unit is irradiated with light strong enough to exceed a saturation capacity of the photoelectric conversion unit, causes the electric charge overflowing from the photoelectric conversion unit to overflow and to be accumulated in the inter-wire capacitor.
(11)

The solid-state imaging element according to any one of (1) to (10), wherein the inter-wire capacitor is configured in a three-dimensional structure.
(12)

An electronic device including a solid-state imaging element including: for each pixel,
a photoelectric conversion unit that photoelectrically converts light into an electric charge;
a first FD (Floating Diffusion) section that accumulates the electric charge transferred from the photoelectric conversion unit via a transfer transistor to convert the electric charge into a pixel signal;
a second FD section that is connected to the first FD section via a connection transistor; and
an inter-wire capacitor that is connected to the second FD section to accumulate the electric charge,
wherein
the inter-wire capacitor is configured to include a first electrode that is connected to the second FD section and a second electrode that faces the first electrode across a dielectric, and
when viewed in a plan view from a logic substrate that is stacked on a sensor substrate on which the photoelectric conversion unit is provided, a wire connected to the second electrode is provided to cover at least the entire second electrode.

Embodiments of the present disclosure are not limited to the above-described embodiments and can be modified in various manners without departing from the scope and spirit of the present disclosure. Moreover, the effects described in this specification are merely examples and are not limited, and other effects may also be present.

### REFERENCE SIGNS LIST

11 Pixel
12 Photoelectric conversion unit
13 Transfer transistor
14 First FD section
15 Connection transistor
16 Second FD section
17 Inter-wire capacitor
18 Reset transistor
19 Amplifier transistor
20 Selection transistor
21 Vertical signal line
22 Second photoelectric conversion unit
23 Third FD section
24 Second connection transistor
25 Second inter-wire capacitor
26 Overflow transistor
27 Third connection transistor
28 Fourth FD section
31 Sensor substrate
32 Logic substrate
33 Semiconductor layer
34 Wire layer
35 Wire layer
36 Semiconductor layer
41 Lower electrode
42 Upper electrode
43 Dielectric film
44 Upper wire
45 Through electrode
46 Lower wire
51 Cu—Cu bonding portion
61 Lower electrode
62 Upper electrode
63 Upper wire
64 Upper wire

1. A solid-state imaging element comprising: for each pixel,
a photoelectric conversion unit that photoelectrically converts light into an electric charge;
a first FD (Floating Diffusion) section that accumulates the electric charge transferred from the photoelectric conversion unit via a transfer transistor to convert the electric charge into a pixel signal;
a second FD section that is connected to the first FD section via a connection transistor; and
an inter-wire capacitor that is connected to the second FD section to accumulate the electric charge,
wherein
the inter-wire capacitor is configured to include a first electrode that is connected to the second FD section and a second electrode that faces the first electrode across a dielectric, and
when viewed in a plan view from a logic substrate that is stacked on a sensor substrate on which the photoelectric conversion unit is provided, a wire connected to the second electrode is provided to cover at least the entire second electrode.

2. The solid-state imaging element according to claim 1, the solid-state imaging element has a structure in which, when the photoelectric conversion unit is irradiated with light strong enough to exceed a saturation capacity of the photoelectric conversion unit, the electric charge overflowing from the photoelectric conversion unit is accumulated in the inter-wire capacitor.

3. The solid-state imaging element according to claim 1, wherein a potential of the wire connected to the second electrode of the inter-wire capacitor is controlled to be at Lo level during a charge accumulation period in which the pixel is exposed to light for a long period of time and the electric charge is accumulated in the photoelectric conversion unit.

4. The solid-state imaging element according to claim 1, wherein the inter-wire capacitor and the wire are disposed in a wire layer on the sensor substrate side.

5. The solid-state imaging element according to claim 1, wherein the inter-wire capacitor and the wire are disposed in a wire layer on the logic substrate side.

6. The solid-state imaging element according to claim 1, wherein the inter-wire capacitor is disposed in a wire layer on the sensor substrate side, and the wire is disposed in a wire layer on the logic substrate side.

7. The solid-state imaging element according to claim 1, wherein the pixel includes a second photoelectric conversion unit having a smaller light-receiving area than the photoelectric conversion unit, and
a third FD section that accumulates an electric charge photoelectrically converted by the second photoelectric conversion unit to convert the electric charge into a pixel signal,
wherein
the inter-wire capacitor is connected to the third FD section via a second connection transistor.

8. The solid-state imaging element according to claim 7, further comprising a second inter-wire capacitor including a third electrode that is connected to the third FD section and a fourth electrode that faces the third electrode across a dielectric.

9. The solid-state imaging element according to claim 8, wherein the inter-wire capacitor and the second inter-wire capacitor are covered by one of a wire connected to the second electrode of the inter-wire capacitor and a wire connected to the third electrode of the second inter-wire capacitor when viewed in a plan view from the logic substrate.

10. The solid-state imaging element according to claim 1, further comprising an overflow transistor that, when the photoelectric conversion unit is irradiated with light strong enough to exceed a saturation capacity of the photoelectric conversion unit, causes the electric charge overflowing from the photoelectric conversion unit to overflow and to be accumulated in the inter-wire capacitor.

11. The solid-state imaging element according to claim 1, wherein the inter-wire capacitor is configured in a three-dimensional structure.

12. An electronic device comprising a solid-state imaging element including: for each pixel,
a photoelectric conversion unit that photoelectrically converts light into an electric charge;
a first FD (Floating Diffusion) section that accumulates the electric charge transferred from the photoelectric conversion unit via a transfer transistor to convert the electric charge into a pixel signal;
a second FD section that is connected to the first FD section via a connection transistor; and
an inter-wire capacitor that is connected to the second FD section to accumulate the electric charge,
wherein
the inter-wire capacitor is configured to include a first electrode that is connected to the second FD section and a second electrode that faces the first electrode across a dielectric, and
when viewed in a plan view from a logic substrate that is stacked on a sensor substrate on which the photoelectric conversion unit is provided, a wire connected to the second electrode is provided to cover at least the entire second electrode.
